(19) United States
(12) Patent Application Publication
(10) Pub. No.: US 2023/0246103 A1
(43) Pub. Date: Aug. 3, 2023

(54) SEMICONDUCTOR DEVICE

(71) Applicant: ROHM CO., LTD., Kyoto (JP)

(72) Inventor: Yusuke KUBO, Kyoto (JP)

(73) Assignee: ROHM CO., LTD., Kyoto (JP)

(21) Appl. No.: 18/091,425

(22) Filed: Dec. 30, 2022

(30) Foreign Application Priority Data
Jan. 31, 2022 (JP) 2022-012548

(51) Int. Cl. H01L 29/78; H01L 29/423; H01L 29/66

(52) U.S. Cl. CPC H01L 29/7813; H01L 29/4236; H01L 29/66734

(57) ABSTRACT

A semiconductor device includes: a semiconductor substrate including a main surface and a back surface opposite to the main surface; a semiconductor layer including a first surface in contact with the main surface of the semiconductor substrate and a second surface opposite to the first surface, and including a gate trench recessed in the second surface; a split gate structure provided in the gate trench; an insulating layer filling the gate trench and covering the second surface of the semiconductor layer; and a trap level region formed in any one of the semiconductor layer and the semiconductor substrate to trap carriers moving from the semiconductor layer.

### CROSS-REFERENCE TO RELATED APPLICATION

This application is based upon and claims the benefit of priority from Japanese Patent Application No. 2022-012548, filed on Jan. 31, 2022, the entire contents of which are incorporated herein by reference.

### TECHNICAL FIELD

The present disclosure relates to a semiconductor device.

### BACKGROUND

A metal-insulator-semiconductor field-effect transistor (MISFET) having a split gate structure is one of trench gate type transistors using a semiconductor device.

The MISFET includes a body diode between a drain and a source. When the body diode is turned off from a state in which a current flows through the body diode in a forward direction (on-state), a reverse recovery current flows through the body diode. The reverse recovery current becomes a factor that increases a switching loss (power loss) of the MISFET. In order to reduce the switching loss associated with such turn-off, it is required to shorten a reverse recovery time. Therefore, even the MISFET having the split-gate structure still has room for improvement in terms of shortening the reverse recovery time.

### SUMMARY

Some embodiments of the present disclosure provide a semiconductor device including: a semiconductor substrate including a main surface and a back surface opposite to the main surface; a semiconductor layer including a first surface in contact with the main surface of the semiconductor substrate and a second surface opposite to the first surface, and including a gate trench recessed in the second surface; a split gate structure provided in the gate trench; an insulating layer filling the gate trench and covering the second surface of the semiconductor layer; and a trap level region formed in any one the semiconductor layer and the semiconductor substrate to trap carriers moving from the semiconductor layer.

### BRIEF DESCRIPTION OF DRAWINGS

The accompanying drawings, which are incorporated in and constitute a part of the specification, illustrate embodiments of the present disclosure.

FIG. 1 is a schematic cross-sectional view (a partially enlarged view of FIG. 2) of an exemplary semiconductor device according to an embodiment in which a trench gate type MISFET having a split gate structure is formed.

FIG. 2 is a schematic cross-sectional view of the semiconductor device (MISFET) having the split gate structure.

FIG. 3 is a schematic cross-sectional view of a semiconductor device showing an example of possible positions of a trap level region.

FIG. 4 is a current waveform diagram in a case of IF=5 A, and shows reverse recovery characteristics for three types of trap level regions formed under first to third conditions and reverse recovery characteristics without a trap level region (a fourth condition).

FIG. 5 is a voltage waveform diagram in the case of IF=5 A, and shows reverse recovery characteristics for three types of trap level regions formed under the first to third conditions and reverse recovery characteristics without a trap level region (the fourth condition).

FIG. 6 is a current waveform diagram in a case of IF=SA, and shows reverse recovery characteristics for four types of trap level regions formed under fifth to eighth conditions and the reverse recovery characteristics without a trap level region (the fourth condition).

FIG. 7 is a voltage waveform diagram in the case of IF=5 A, and shows reverse recovery characteristics for four types of trap level regions formed under the fifth to eighth conditions and reverse recovery characteristics without a trap level region (the fourth condition).

FIG. 8 is a current waveform diagram in a case of IF=20 A, and shows reverse recovery characteristics for three types of trap level regions formed under the first to third conditions and reverse recovery characteristics without a trap level region (the fourth condition).

FIG. 9 is a voltage waveform diagram in the case of IF=20 A, and shows reverse recovery characteristics for three types of trap level regions formed under the first to third conditions and reverse recovery characteristics without a trap level region (the fourth condition).

FIG. 10 is a current waveform diagram in the case of IF=20 A, and shows reverse recovery characteristics of four types of trap level regions formed under the fifth to eighth conditions and reverse recovery characteristics without a trap level region (the fourth condition).

FIG. 11 is a voltage waveform diagram in the case of IF=20 A, and shows reverse recovery characteristics for four types of trap level regions formed under the fifth to eighth conditions and reverse recovery characteristics without a trap level region (the fourth condition).

FIG. 12 is a table showing measurement results of various characteristics under the first to eighth conditions.

### DETAILED DESCRIPTION

Reference will now be made in detail to various embodiments, examples of which are illustrated in the accompanying drawings. In the following detailed description, numerous specific details are set forth in order to provide a thorough understanding of the present disclosure. However, it will be apparent to one of ordinary skill in the art that the present disclosure may be practiced without these specific details. In other instances, well-known methods, procedures, systems, and components have not been described in detail so as not to unnecessarily obscure aspects of the various embodiments.

Embodiments of a semiconductor device of the present disclosure will now be described with reference to the accompanying drawings. It should be noted that, for simplicity and clarity of explanation, components shown in the drawings are not necessarily drawn to scale. In order to facilitate understanding, characteristic portions may be enlarged, and the dimensional ratio of each component is not necessarily the same in each drawing. Further, in order to facilitate understanding, hatching may be omitted in cross-sectional views. The accompanying drawings merely illustrate embodiments of the present disclosure and should not be considered as limiting the present disclosure.

The following detailed description includes devices, systems, and methods embodying exemplary embodiments of the present disclosure. This detailed description is for illustrative purposes only and is not intended to limit the embodiments of the present disclosure or the applications and uses of such embodiments.

### [Structure of Semiconductor Device (MISFET) Having Split Gate Structure]

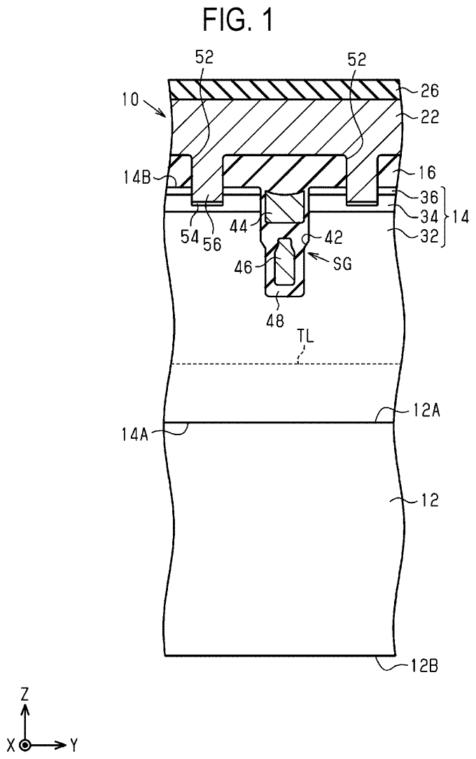

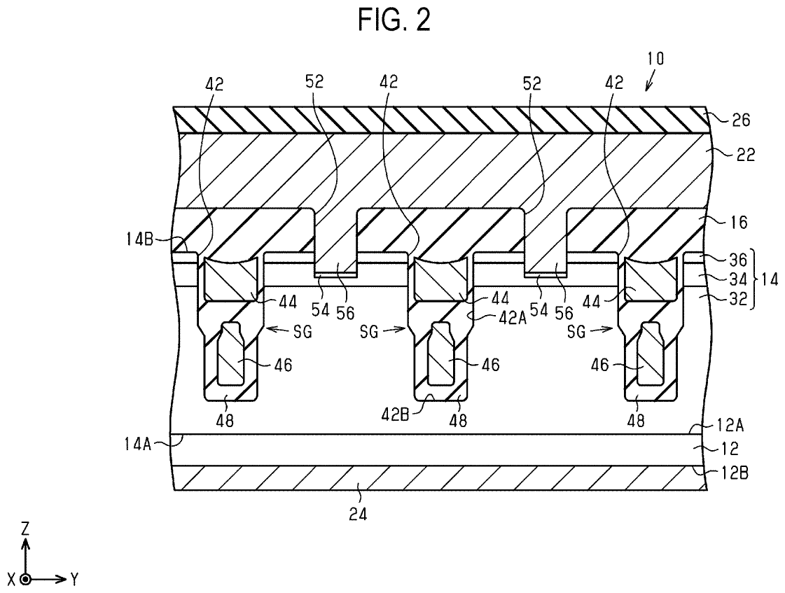

FIGS. 1 and 2 are schematic cross-sectional views of an exemplary semiconductor device according to one embodiment. FIG. 1 is a partially enlarged view of FIG. 2. However, in order to facilitate understanding, some components are shown in different dimensional ratios between FIG. 1 and FIG. 2.

As shown in FIG. 2, a semiconductor device 10 is formed as a trench gate type metal-insulator-semiconductor field effect transistor (MISFET) having a split gate structure SG. The semiconductor device 10 includes a semiconductor substrate 12, a semiconductor layer 14, and an insulating layer 16. The semiconductor substrate 12 is, for example, a silicon (Si) substrate. The semiconductor substrate 12 has a main surface 12A (an upper surface in FIG. 2) and a back surface 12B (a lower surface in FIG. 2) opposite to the main surface 12A.

Hereinafter, the term “plan view” used in the present disclosure refers to viewing an object (the semiconductor device 10 or its components) in a Z-axis direction of mutually orthogonal XYZ axes (for example, FIG. 2). The Z-axis corresponds to a direction orthogonal to the main surface 12A (and the back surface 12B) of the semiconductor substrate 12. In the following, for ease of explanation, a +Z direction is defined as upward, a —Z direction is defined as downward, a +X direction is defined as rightward, and a —X direction is defined as leftward.

The semiconductor layer 14 is provided on the main surface 12A of the semiconductor substrate 12. The semiconductor layer 14 includes a first surface 14A (a lower surface in FIG. 2) and a second surface 14B (an upper surface in FIG. 2) opposite to the first surface 14A. The first surface 14A of the semiconductor layer 14 is in contact with the main surface 12A of the semiconductor substrate 12. For example, the semiconductor layer 14 can be formed so as to cover the entire main surface 12A of the semiconductor substrate 12. The semiconductor layer 14 is formed of, for example, a Si epitaxial layer.

The insulating layer 16 is provided on the second surface 14B of the semiconductor layer 14. In FIG. 2, the insulating layer 16 is shown as a single layer, but may include multiple layers. For example, the insulating layer 16 may include at least one of a silicon oxide (SiO₂) layer and a silicon nitride (SiN) layer. The insulating layer 16 is also referred to as an inter-layer dielectric (ILD).

The semiconductor device 10 further includes a source electrode layer 22, a drain electrode layer 24, and a passivation layer 26. The source electrode layer 22 is provided on the insulating layer 16. Although not shown, the semiconductor device 10 further includes a gate electrode layer provided on the insulating layer 16. The drain electrode layer 24 is provided on the back surface 12B of the semiconductor substrate 12. For example, the drain electrode layer 24 can be formed to cover the entire back surface 12B of the semiconductor substrate 12.

Although not shown in detail, the passivation layer 26 is formed so as to cover the source electrode layer 22 and the gate electrode layer while exposing, as electrode pads, a portion of the source electrode layer 22 and a portion of the gate electrode layer. The passivation layer 26 may include, for example, at least one of a SiO₂ layer and a SiN layer.

The semiconductor substrate 12 provided with the drain electrode layer 24 functions as a drain region of the semiconductor device 10 (MISFET). The semiconductor layer 14 includes a drift region 32 formed on the semiconductor substrate 12 (the drain region), a body region 34 formed on the drift region 32, and a source region 36 formed on the body region 34.

For example, the semiconductor substrate 12 corresponding to the drain region is formed as an n-type region containing n-type impurities. The drift region 32 is formed as an n-type region having an n-type impurity concentration lower than that of the semiconductor substrate 12 (the drain region). The body region 34 is formed as a p-type region containing p-type impurities. The source region 36 is formed as an n-type region having an n-type impurity concentration higher than that of the drift region 32. Examples of n-type impurities may include phosphorus (P) and arsenic (As). Examples of p-type impurities may include boron (B) and aluminum (Al).

The semiconductor layer 14 includes a plurality of gate trenches 42 recessed in the second surface 14B (the upper surface in FIG. 2) of the semiconductor layer 14. As shown in FIG. 2, at least some of the plurality of gate trenches 42 are arranged parallel to one another at regular intervals.

A split gate structure SG is provided in each gate trench 42. The split gate structure SG includes a buried gate electrode 44 and a field plate electrode 46 which are separated from each other in the gate trench 42. The split gate structure SG also includes a trench insulating layer 48 filled in the gate trench 42. Since the split gate structures SG in each gate trench 42 have the same configuration, one split gate structure SG and a related structure around it will be described below.

In the split gate structure SG, the buried gate electrode 44 and the field plate electrode 46 are separated from each other by the trench insulating layer 48. The buried gate electrode 44 is located above the field plate electrode 46 in the gate trench 42. The trench insulating layer 48 covers a sidewall 42A and a bottom wall 42B of the gate trench 42.

The buried gate electrode 44 and the field plate electrode 46 may be formed of, for example, conductive polysilicon. The trench insulating layer 48 may be formed of, for example, SiO₂. Further, the trench insulating layer 48 may be formed of the same material as the insulating layer 16 or may be formed of a material different from that of the insulating layer 16. In other words, an insulating layer filling the gate trench 42 and covering the second surface 14B (the upper surface in FIG. 2) of the semiconductor layer 14 may be formed of a single insulating layer, or may be formed of a plurality of insulating layers.

The insulating layer 16 covers the buried gate electrode 44 and the trench insulating layer 48 which are provided in the gate trench 42. The insulating layer 16 includes a plurality of source trenches 52 arranged side by side on both sides (right and left sides in FIG. 2) of the gate trench 42 in a plan view. Each source trench 52 extends through the insulating layer 16 and the source region 36 to reach the body region 34. A contact region 54 is formed at a bottom of each source trench 52. For example, the contact region 54 is formed as a p-type region having a p-type impurity concentration higher than that of the body region 34. The source trench 52 is filled with a source connection conductor 56. This source connection conductor 56 is connected to the source electrode layer 22. Accordingly, the contact region 54 is electrically connected to the source electrode layer 22 via the source connection conductor 56.

In the gate trench 42, the trench insulating layer 48 is also interposed between the buried gate electrode 44 and the semiconductor layer 14. In other words, the buried gate electrode 44 and the semiconductor layer 14 are separated from each other (in the Y direction in FIG. 2) by the trench insulating layer 48. Although not shown in detail, the buried gate electrode 44 is electrically connected to the gate electrode layer on the insulating layer 16 via a gate connection conductor penetrating the insulating layer 16. Therefore, a control voltage is applied to the buried gate electrode 44 via the gate electrode layer and the gate connection conductor. When the control voltage equal to or higher than a predetermined threshold voltage is applied to the buried gate electrode 44, a channel is formed (in the Z direction in FIG. 2) in the body region 34 (p-type region). The channel brings the source region 36 (n-type region) and the drift region 32 (n-type region) into electric conduction, thereby turning the MISFET on.

Further, the trench insulating layer 48 surrounds the field plate electrode 46. Although not shown in detail, the field plate electrode 46 is electrically connected to the source electrode layer 22 via a field plate connection conductor penetrating the insulating layer 16 and the trench insulating layer 48. Therefore, during operation of the semiconductor device 10, a source voltage is applied to the field plate electrode 46 via the source electrode layer 22 and the field plate connection conductor. By applying the source voltage to the field plate electrode 46, an electric field concentration at a bottom of the gate trench 42 can be alleviated, thereby improving a withstand voltage of the MISFET.

### [Reverse Recovery Operation of Body Diode]

The MISFET formed by the semiconductor device 10 structurally includes a body diode between its drain and source. In the structure of FIG. 2, the body diode is formed by the body region 34 (p-type region), the drift region 32 (n-type region), and the semiconductor substrate 12 (n-type region). When the body diode is turned off from a state in which a current flows through the body diode in a forward direction (on-state), a reverse recovery current flows through the body diode.

For example, the semiconductor device 10 can be applied to a switching element such as an inverter circuit. In this case, an operating state may occur in which a current flows through the body diode of the semiconductor device 10 (MISFET) in the forward direction. When the body diode is in the on-state, the drift region 32 becomes a state of being filled with a large number of carriers. When a reverse bias is applied to the body diode in this state, that is, when a potential of the source electrode layer 22 becomes lower than that of the drain electrode layer 24, the body diode is turned off.

When the reverse bias is applied to the body diode, holes among carriers existing in the drift region 32 move toward the source electrode layer 22, while electrons among the carriers existing in the drift region 32 move toward the drain electrode layer 24. This movement of carriers causes a current to flow through the body diode in the reverse direction. As a result, a depletion layer spreads into the drift region 32 from a pn junction at a boundary between the body region 34 and the drift region 32 toward the first surface 14A of the semiconductor layer 14.

The current that flows through the body diode in the reverse direction at turn-off of the body diode is referred to as a reverse recovery current. The reverse recovery current first increases and then decreases as the number of carriers discharged from the drift region 32 decreases. A time from when the forward current of the diode becomes 0 (zero) to when the reverse recovery current decreases to 10% of its maximum value is referred to as a reverse recovery time. A value obtained by integrating the current over the period of the reverse recovery time is referred to as a reverse recovery charge amount.

### [Trap Level Region of Semiconductor Device]

As shown in FIG. 1, the MISFET formed by the semiconductor device 10 includes a trap level region TL. The drain electrode layer 24 (see FIG. 2) is not shown in FIG. 1.

The trap level region TL is formed in any one the semiconductor layer 14 and the semiconductor substrate 12 to trap carriers moving from the semiconductor layer 14. The trap level region TL is a region caused by crystal defects formed by irradiating the trap level region TL with charged particles from the back surface 12B of the semiconductor substrate 12. Since many recombination centers that trap and recombine carriers so as to extinguish the carriers are present in the trap level region TL, carriers (electrons) that move from the semiconductor layer 14 when the body diode of the semiconductor device 10 is turned off can be quickly extinguished. As a result, the reverse recovery current and the reverse recovery time can be reduced.

The trap level region TL has a region center at the irradiation position of the charged particles in the semiconductor layer 14 or in the semiconductor substrate 12, and is locally formed so as to spread from the region center in a thickness direction over a predetermined spread range (for example, a thickness of about 1 μm or more and 3 μm or less). The thickness direction refers to a direction orthogonal to the back surface 12B of the semiconductor substrate 12 irradiated with charged particles (that is, the Y-axis direction).

In the example of FIG. 1, the trap level region TL is formed in the semiconductor layer 14. For example, the trap level region TL can be formed in the semiconductor layer 14 at a position between a bottom surface of the gate trench 42 and the first surface 14A (the lower surface in FIG. 1) of the semiconductor layer 14. As described above, when the body diode is turned off, the depletion layer spreads into the drift region 32 from the pn junction toward the first surface 14A of the semiconductor layer 14. When the depletion layer spreads to the maximum, an edge of the depletion layer can extend beyond the bottom surface of the gate trench 42. Therefore, by forming the trap level region TL at a position between the bottom surface of the gate trench 42 and the first surface 14A of the semiconductor layer 14, the effect of trapping carriers (electrons) that move from the semiconductor layer 14 toward the drain electrode layer 24 during the reverse recovery operation can be enhanced.

Here, the position of the edge of the depletion layer when the depletion layer spreads to the maximum at the turn-off of the body diode can be predicted to some extent according to design conditions and operation conditions of the semiconductor device 10. In the example of FIG. 1, the trap level region TL is formed to have the region center of the trap level region TL at a position between a center position between the bottom surface of the gate trench 42 and the first surface 14A of the semiconductor layer 14 and the first surface 14A of the semiconductor layer 14. In this case, the region center of the trap level region TL can be set, for example, at a position near the edge of the depletion layer when the depletion layer spreads to the maximum. By setting the trap level region TL (that is, the irradiation position of the charged particles) in the vicinity of the edge of the depletion layer, the effect of trapping carriers during the reverse recovery operation can be enhanced.

For example, the trap level region TL is formed by performing heat treatment at a low temperature (low-temperature annealing) after being irradiated with charged particles. As the charged particles, for example, protons, ³He⁺⁺, ⁴He⁺⁺, or electron beams are used. Protons are an example of first heavy particles, and ³He⁺⁺ and ⁴He⁺⁺ are examples of second heavy particles having a greater particle mass than the first heavy particles. Helium nuclei (³He⁺⁺ or ⁴He⁺⁺) with a large mass can narrow a distribution area of the recombination centers in the thickness direction, so that the recombination centers can be locally distributed in a narrow range in the thickness direction.

Further, by performing the low-temperature annealing, the charged particles are activated. For example, when helium nuclei (³He⁺⁺ or ⁴He⁺⁺) are selected as the charged particles, by performing heat treatment at 320 degrees C. or higher and 380 degrees C. or lower (for example, 350 degrees C.) for 30 minutes or longer and 120 minutes or shorter (for example, 60 minutes), the introduced helium nuclei can be activated.

Here, when the energy for irradiation with the charged particles is increased, a range of the charged particles is increased, so that the trap level region TL is formed at a position far from the back surface 12B of the semiconductor substrate 12. Conversely, when the energy for irradiation with the charged particles is decreased, the range of the charged particles is decreased, so that the trap level region TL is formed at a position near the back surface 12B of the semiconductor substrate 12. Therefore, the irradiation energy of the charged particles is set according to an arrangement of the trap level regions TL. An irradiation dose of the charged particles can be set to, for example, 5×10¹¹ particles/cm² or more and 5×10¹² particles/cm² or less.

### [Possible Position of Trap Level Region]

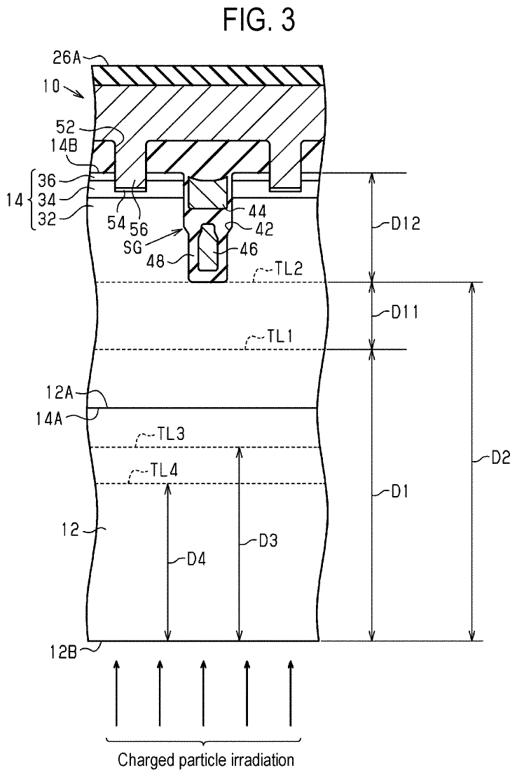

FIG. 3 is a schematic cross-sectional view of the semiconductor device 10 showing an example of possible positions of the trap level region having the carrier trapping effect. Although FIG. 3 shows four trap level regions TL1 to TL4 as an example, possible positions are not limited to the positions shown in FIG. 3. Also, although FIG. 3 shows the four trap level regions TL1 to TL4 together for ease of comparison of positions, only one trap level region (for example, the trap level region TL in FIG. 1) is formed in any one the semiconductor layer 14 and the semiconductor substrate 12.

In FIG. 3, the trap level region TL1 corresponds to the trap level region TL shown in FIG. 1. As described with reference to FIG. 1, the trap level region TL1 is formed so as to have the region center of the trap level region TL1 at the position between the center position between the bottom surface of the gate trench 42 and the first surface 14A of the semiconductor layer 14 and the first surface 14A of the semiconductor layer 14.

From the viewpoint of irradiation with the charged particles, the trap level region TL1 is formed in the semiconductor layer 14 at a position distanced from the back surface 12B of the semiconductor substrate 12 by a distance D1. In other words, the trap level region TL1 is formed at a depth position distanced from the bottom surface of the gate trench 42 by a distance D11, in a depth direction of the gate trench 42 from the second surface 14B (the upper surface in FIG. 3) of the semiconductor layer 14 toward the first surface 14A (the lower surface in FIG. 3) thereof. The position distanced by the distance D1 (distance D11), that is, the position of the trap level region TL1, can be set, for example, at a position near the edge of the depletion layer when the depletion layer spreads to the maximum.

The trap level region TL2 is formed at a position adjacent to the bottom surface of the gate trench 42. In this example, the trap level region TL2 does not intersect the gate trench 42. The trap level region TL2 is formed in the semiconductor layer 14 at a position distanced from the back surface 12B of the semiconductor substrate 12 by a distance D2 (=D1+D11). In other words, the trap level region TL2 is formed at a position distanced from an opening surface of the gate trench 42 (the second surface 14B of the semiconductor layer 14) by a distance corresponding to a depth D12 of the gate trench 42 (or a distance slightly larger than the depth D12). Thus, the trap level region TL2 formed at the position adjacent to the bottom surface of the gate trench 42 also has the effect of trapping carriers.

The trap level region TL3 is formed in the semiconductor substrate 12 at a position distanced from the back surface 12B of the semiconductor substrate 12 by a distance D3. Further, the trap level region TL4 is formed in the semiconductor substrate 12 at a position distanced from the back surface 12B of the semiconductor substrate 12 by a distance D4 (<distance D3). When the body diode is turned off, carriers (electrons) move from the semiconductor layer 14 toward the drain electrode layer 24 via the semiconductor substrate 12. Therefore, the trap level regions TL3 and TL4 formed in the semiconductor substrate 12 also have the effect of trapping carriers.

As an example, when the semiconductor device 10 having the split gate structure SG is manufactured to have a device withstand voltage of about 150 V, a thickness of the semiconductor substrate 12 (a distance from the main surface 12A to the back surface 12B) can be about 93 μm, a thickness of the semiconductor layer 14 (a distance from the first surface 14A to the second surface 14B) can be about 15 μm, a distance from an upper surface of the passivation layer 26 to the second surface 14B of the semiconductor layer 14 can be about 6 μm, and the depth D12 (a distance in the depth direction) of the gate trench 42 can be about 3 μm or more and 10 μm or less (for example, about 7 μm).

In this case, for example, the distance D1 can be set to approximately 96 μm and the distance D11 can be set to approximately 5 μm. Further, the distance D2 can be set to, for example, approximately 101 (=96(D1)+5(D11)) μm. For example, when the trap level region is formed in the semiconductor layer 14, the trap level region can be formed at a depth position within 10 μm from the bottom surface of the gate trench 42 in the depth direction of the gate trench 42. Further, for example, the distance D3 can be set to approximately 87 μm and the distance D4 can be set to approximately 82 μm. For example, when the trap level region is formed in the semiconductor substrate 12, the trap level region can be formed at a depth position within 15 μm from the main surface 12A of the semiconductor substrate 12 in the direction from the main surface 12A of the semiconductor substrate 12 to the back surface 12B thereof.

### [Relationships Between Trap Level Region Formation Conditions and Reverse Recovery Characteristics]

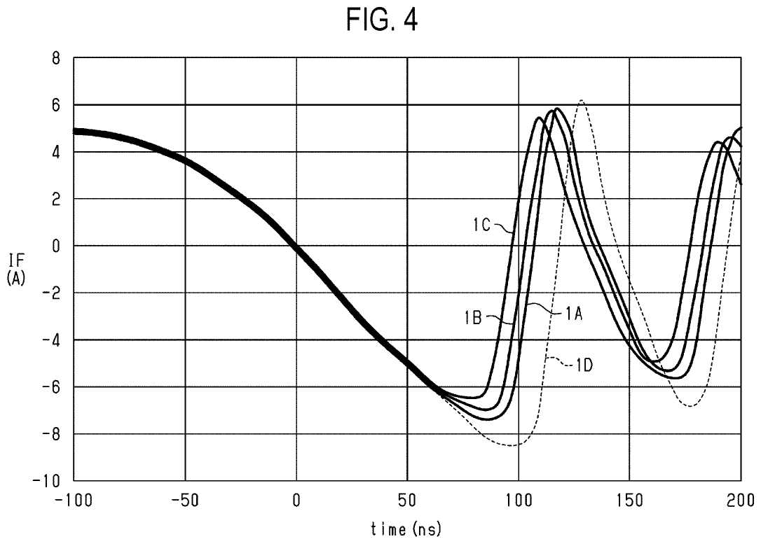

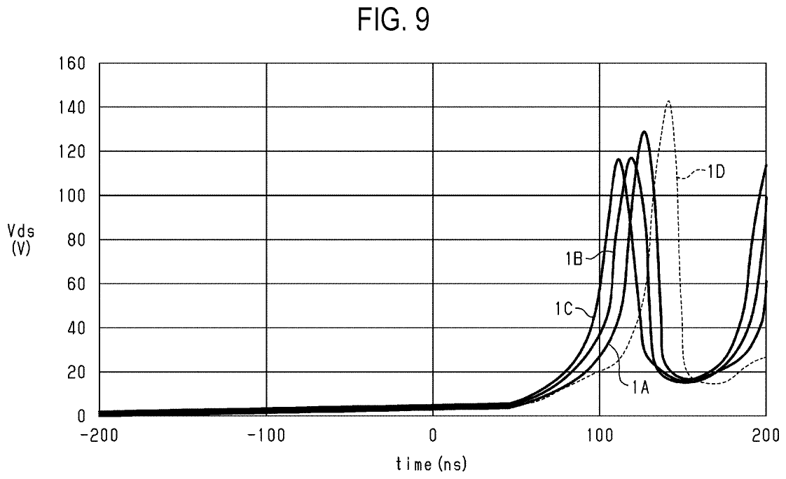

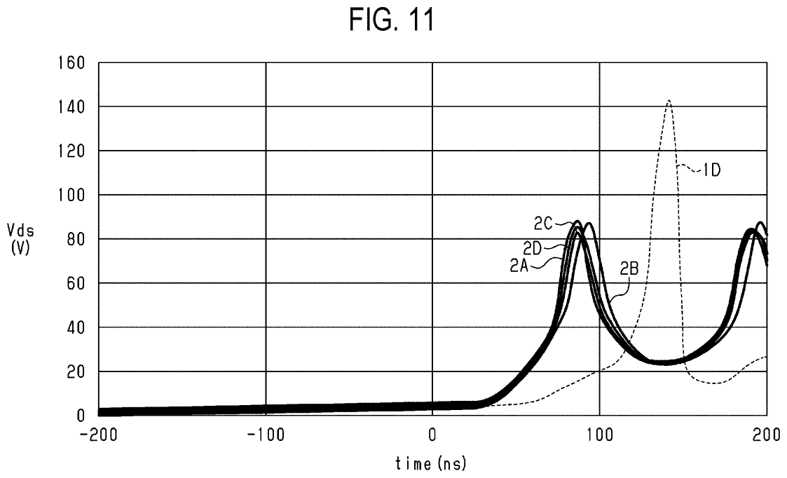

Next, relationships between conditions for forming trap level regions and reverse recovery characteristics will be described with reference to FIGS. 4 to 12. Here, description will be made by comparing reverse recovery characteristics for seven types of trap level regions formed under seven different conditions and reverse recovery characteristics without a trap level region.

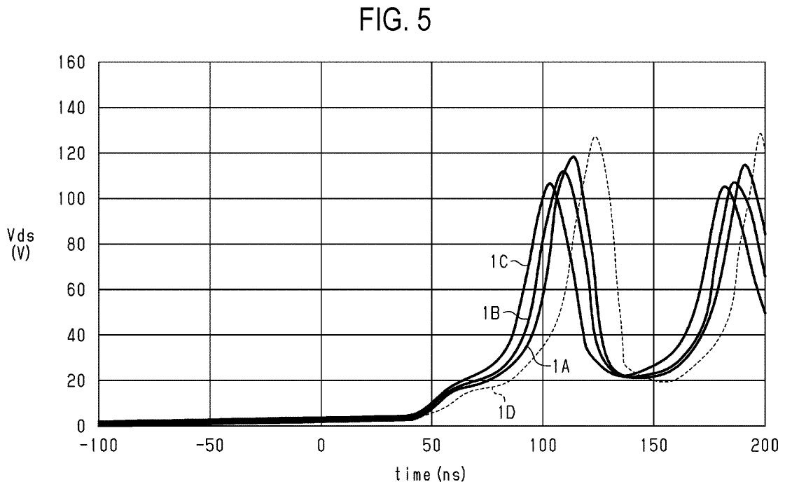

FIGS. 4 and 5 are graphs showing reverse recovery characteristics for three types of trap level regions formed under a first condition 1A, a second condition 1B, and a third condition 1C and reverse recovery characteristics without trap level region (a fourth condition 1D). FIG. 4 is a current waveform diagram showing a relationship between a forward current IF flowing through the body diode of the semiconductor device 10 (MISFET) and time, and FIG. 5 is a voltage waveform diagram showing a relationship between a drain-source voltage Vds of the semiconductor device 10 and time. The graphs of FIGS. 4 and 5 show measurement results when the forward current IF is, for example, 5 A (see FIG. 4).

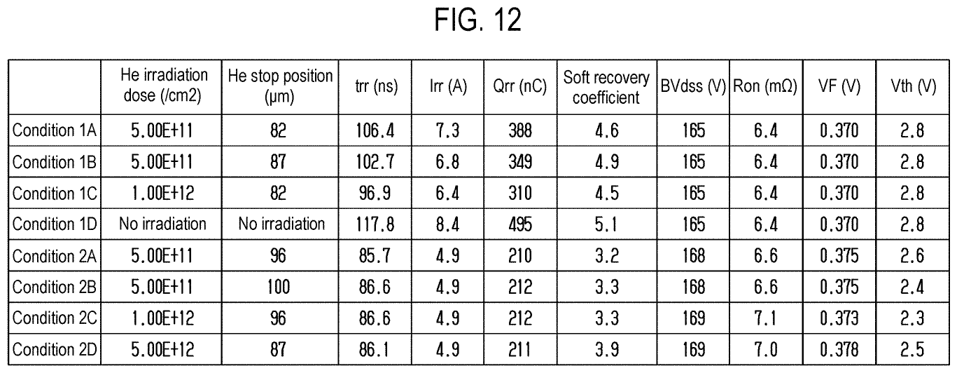

As shown in FIG. 12, in the first to third conditions 1A to 1C, helium nuclei (for example, ⁴He⁺⁺) are used as charged particles forming the trap level regions. In the first and second conditions 1A and 1B, the irradiation dose of helium nuclei is set to 5×10¹¹ particles/cm², and in the third condition 1C, the irradiation dose of helium nuclei is set to 1×10¹² particles/cm². In the fourth condition 1D, no trap level region is formed because no charged particles are irradiated.

Further, in the first and third conditions 1A and 1C, the trap level region is formed at the position distanced by the distance D4 (that is, in the semiconductor substrate 12) in FIG. 3. In the second condition 1B, the trap level region is formed at the position distanced by the distance D3 (that is, in the semiconductor substrate 12) in FIG. 3.

As shown in FIGS. 4 and 12, comparing the first to fourth conditions 1A to 1D, a reverse recovery current Irr, a reverse recovery time trr, and a reverse recovery charge amount Qrr are most reduced under the third condition 1C. From this result, it can be recognized that the reverse recovery characteristics are further improved when the charged particles are irradiated into the semiconductor substrate 12 at an irradiation position (stop position) farther from the back surface 12B of the semiconductor substrate 12 and the irradiation dose thereof is high. Further, among the first to third conditions 1A to 1C, a soft recovery coefficient is the lowest under the third condition 1C, indicating that a soft recovery property with excellent noise resistance is obtained. All of the first to third conditions 1A to 1C exhibit the reverse recovery characteristics superior to the fourth condition 1D. Therefore, it can be recognized that the trap level region produces the carrier trapping effect to improve the reverse recovery characteristics.

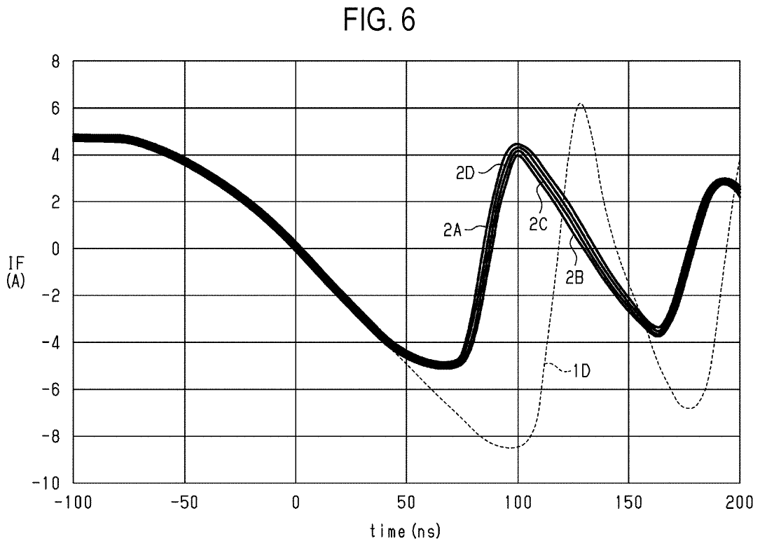

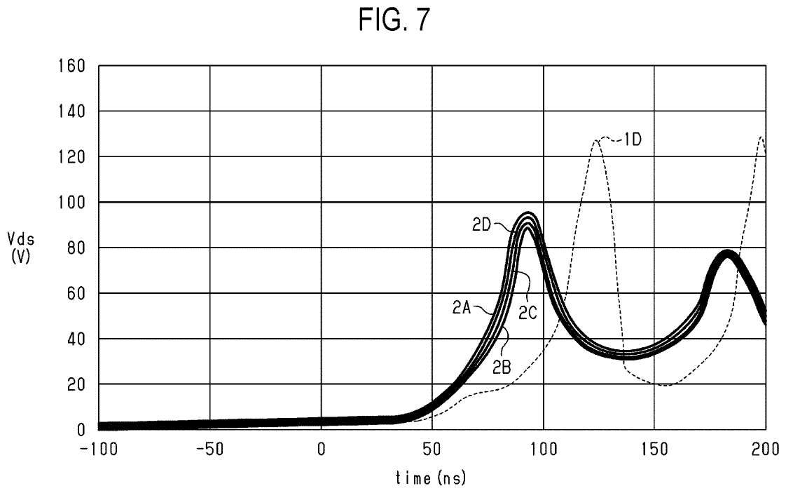

FIGS. 6 and 7 are graphs showing reverse recovery characteristics for four types of trap level regions formed under a fifth condition 2A, a sixth condition 2B, a seventh condition 2C, and an eighth condition 2D and the reverse recovery characteristics without a trap level region (the fourth condition 1D). FIG. 6 is a current waveform diagram showing a relationship between the forward current IF flowing through the body diode of the semiconductor device 10 (MISFET) and time, and FIG. 7 is a voltage waveform diagram showing a relationship between the drain-source voltage Vds of the semiconductor device 10 and time. The graphs of FIGS. 6 and 7 show measurement results when the forward current IF is, for example, 5 A (see FIG. 6).

As shown in FIG. 12, in the fifth to eighth conditions 2A to 2D, helium nuclei (for example, ⁴He⁺⁺) are used as charged particles forming the trap level regions. In the fifth and sixth conditions 2A and 2B, the irradiation dose of helium nuclei is set to 5×10¹¹ particles/cm², in the seventh condition 2C, the irradiation dose of helium nuclei is set to 1×10¹² particles/cm², and in the eighth condition 2D, the irradiation dose of helium nuclei is set to 5×10¹² particles/cm².

Further, in the fifth and seventh conditions 2A and 2C, the trap level region is formed at the position distanced by the distance D1 (that is, near the edge of the depletion layer in the semiconductor layer 14) in FIG. 3. In the sixth condition 2B, the trap level region is formed at the position distanced by the distance D2 (that is, near the bottom surface of the gate trench 42 in the semiconductor layer 14) in FIG. 3. In the eighth condition 2D, the trap level region is formed at the position distanced by the distance D3 (that is, in the semiconductor substrate 12) in FIG. 3.

As shown in FIGS. 6 and 12, comparing the fourth to eighth conditions 1D and 2A to 2D, the reverse recovery current Irr, the reverse recovery time trr, and the reverse recovery charge amount Qrr are almost the same among the fifth to seventh conditions 2A to 2C. On the other hand, the fifth to seventh conditions 2A to 2C exhibit reverse recovery characteristics superior to the first to third conditions 1A to 1C. From this result, it can be recognized that when the charged particles are irradiated into the semiconductor layer 14, the reverse recovery characteristics are improved (compared to when they are irradiated into the semiconductor substrate 12). Further, the fifth to seventh conditions 2A to 2C show soft recovery properties superior to the first to third conditions 1A to 1C. On the other hand, the eighth condition 2D shows almost the same reverse recovery characteristics as the fifth to seventh conditions 2A to 2C, but the soft recovery characteristics are lower than those of the fifth to seventh conditions 2A to 2C.

Here, characteristics other than the reverse recovery characteristics for the first to third conditions 1A to 1C and the fifth to eighth conditions 2A to 2D will be examined with reference to FIG. 12. As shown in FIG. 12, it can be recognized that there is a tendency to improve a drain-source breakdown voltage BVdss when the charged particles are irradiated to the irradiation position (stop position) farther from the back surface 12B of the semiconductor substrate 12 and the irradiation amount thereof is increased. On the other hand, it can be recognized that an on-resistance Ron and a forward voltage VF of the body diode tend to increase gradually and a threshold voltage Vth of the MISFET tends to decrease gradually. The increase in the forward voltage VF of the body diode may cause an increase in leakage current between the drain and the source, and the decrease in the threshold voltage Vth may cause a decrease in reliability such as occurrence of a self-turn-on phenomenon.

Therefore, from the viewpoint of improving the reverse recovery characteristics while maintaining good on-resistance characteristics, current leakage resistance characteristics, and good threshold voltage, the trap level region formed under the fifth condition 2A is most desirable.

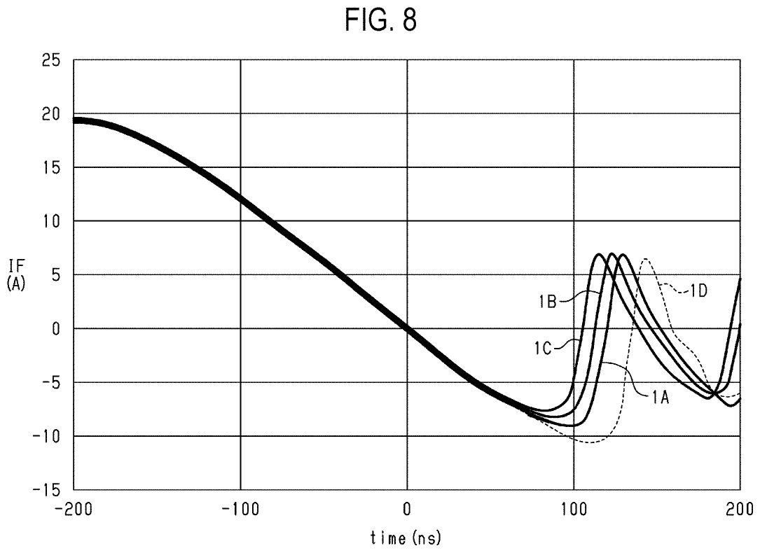

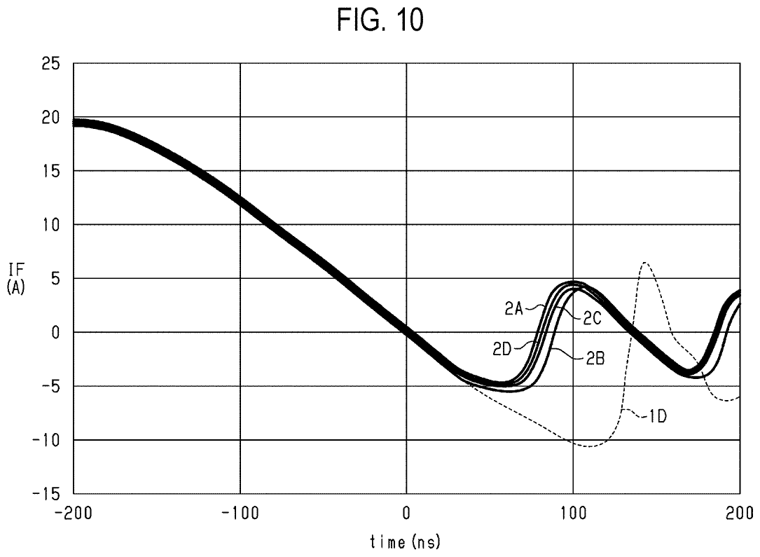

FIGS. 8 to 11 are graphs showing measurement results of reverse recovery characteristics when the forward current IF is, for example, 20 A (see FIGS. 8 and 10) for the first to fourth conditions 1A to 1D and the fifth to eighth conditions 2A to 2D. As shown in FIGS. 8 and 10, even when the forward current IF is 20 A, similarly to when the forward current IF is 5 A, all of the first to third conditions 1A to 1C and the fifth to eighth conditions 2A to 2D exhibit reverse recovery characteristics superior to the fourth condition 1D. Therefore, it can be recognized that the trap level region produces the carrier trapping effect to improve the reverse recovery characteristics. Further, although not shown here, measurement results of characteristics other than the reverse recovery characteristics also show the same tendency as the results obtained when the forward current IF is 5 A (see FIG. 12). Therefore, the trap level region formed under the fifth condition 2A is most desirable from the viewpoint of improving the reverse recovery characteristics while maintaining good on-resistance characteristics, current leakage resistance characteristics, and good threshold voltage.

### [Operations of Semiconductor Device]

The semiconductor device 10 including the split gate structure SG includes the trap level region TL formed in any one the semiconductor layer 14 and the semiconductor substrate 12 to trap carriers moving from the semiconductor layer 14. In the example of FIG. 1, the trap level region TL is formed in the semiconductor layer 14.

When a reverse bias is applied to the body diode of the semiconductor device 10, a reverse recovery current flows through the body diode. During such a reverse recovery operation, the trap level region TL traps carriers moving from the semiconductor layer 14 to reduce the reverse recovery current. This can reduce the reverse recovery time.

The semiconductor device 10 of one embodiment has the following advantages.

(1) The semiconductor device 10 including the split gate structure SG includes the trap level region TL (TL1) formed in the semiconductor layer 14 to trap carriers moving from the semiconductor layer 14. During the reverse recovery operation of the body diode of the semiconductor device 10, the trap level region TL (TL1) traps carriers moving from the semiconductor layer 14 to reduce the reverse recovery current. This can reduce the reverse recovery time.

(2) The trap level region TL (TL1) is formed in the semiconductor layer 14 at a position between the bottom surface of the gate trench 42 and the first surface 14A of the semiconductor layer 14. With this configuration, the effect of trapping carriers moving in the semiconductor layer 14 can be enhanced to reduce the reverse recovery current and the reverse recovery time.

(3) The trap level region TL (TL1) is formed at a position between the center position between the bottom surface of the gate trench 42 and the first surface 14A of the semiconductor layer 14 and the first surface 14A of the semiconductor layer 14. For example, the trap level region TL (TL1) can be formed at a position near the edge of the depletion layer when the depletion layer spreads a maximum in the semiconductor layer 14 during the reverse recovery operation of the body diode. With this configuration, the effect of trapping carriers moving in the semiconductor layer 14 can be enhanced to reduce the reverse recovery current and the reverse recovery time.

(4) The trap level region TL2 is formed at a position between the center position between the bottom surface of the gate trench 42 and the first surface 14A of the semiconductor layer 14 and the bottom surface of the gate trench 42. For example, the trap level region TL2 is formed at a depth position within 10 μm from the bottom surface of the gate trench 42, in the depth direction of the gate trench 42 from the second surface 14B of the semiconductor layer 14 toward the first surface 14A thereof. Also with this configuration, the reverse recovery current and the reverse recovery time can be reduced by the effect of trapping carriers moving in the semiconductor layer 14.

(5) The trap level regions TL3 and TL4 are formed at a depth position within 15 μm from the main surface 12A of the semiconductor substrate 12, in the direction from the main surface 12A of the semiconductor substrate 12 toward the back surface 12B thereof. Thus, even when the trap level regions TL3 and TL4 are formed in the semiconductor substrate 12, the reverse recovery current and the reverse recovery time can be reduced by the effect of trapping carriers that have moved from the semiconductor layer 14 to the semiconductor substrate 12.

(6) By using helium nuclei (³He⁺⁺ or ⁴He⁺⁺) as charged particles forming the trap level region TL (TL1, TL2, TL3, or TL4), the distribution area of the recombination centers in the thickness direction can be narrowed. As a result, the recombination centers can be locally distributed in a narrow range with respect to the thickness direction of the trap level region TL.

### [Modifications]

Each of the above-described embodiments can be modified and implemented as follows. In addition, the above-described embodiments and the following modifications can be implemented in combination unless technically contradictory.

The positions of the trap level regions are not limited to the positions described in the above-described embodiments (that is, the positions of the trap level regions TL1 to TL4). The trap level regions may be formed in the semiconductor layer 14 at positions between the bottom surface of the gate trench 42 and the first surface 14A of the semiconductor layer 14. Therefore, the trap level regions may be formed at positions between the center position between the bottom surface of the gate trench 42 and the first surface 14A of the semiconductor layer 14 and the first surface 14A of the semiconductor layer 14, or may be formed at positions between the center position between the bottom surface of the gate trench 42 and the first surface 14A of the semiconductor layer 14 and the bottom surface of the gate trench 42.

From the viewpoint of improving the reverse recovery characteristics, the trap level regions may be formed in the semiconductor layer 14 at positions intersecting the split gate structure SG within a range that does not affect the operation of the split gate structure SG.

The term “on” as used in the present disclosure includes the meanings of “on” and “above” unless clearly stated otherwise in the context. Therefore, the expression “a first element is mounted on a second element” is intended that in some embodiments, the first element can be directly arranged on the second element while being in contact with the second element, while in other embodiments, the first element can be arranged above the second element without being in contact with the second element. That is, the term “on” does not exclude a structure in which other elements are formed between the first and second elements.

The z direction used in the present disclosure does not necessarily have to be the vertical direction, and it does not have to be exactly the same as the vertical direction. Therefore, in various structures (for example, the structure shown in FIG. 2) according to the present disclosure, “upper” and “lower” in the Z-axis direction described herein are not limited to “upper” and “lower” in the vertical direction, respectively. For example, the X-axis direction may be the vertical direction, or the Y-axis direction may be the vertical direction.

Ordinal numbers such as “first” and “second” used in the present disclosure are merely used to clearly distinguish components, and it is not essential to have the components in order.

### [Supplementary Notes]

The technical ideas that can be recognized from the above-described embodiments and modifications are described below. In addition, components described in Supplementary Notes are labeled with the reference numerals of the corresponding components in the embodiments. The reference numerals are provided as examples to aid understanding, and the components described in Supplementary Notes should not be limited to the components indicated by the reference numerals.

### (Supplementary Note A1)

A semiconductor device (10) including:

a semiconductor substrate (12) including a main surface (12A) and a back surface (12B) opposite to the main surface (12A);

a semiconductor layer (14) including a first surface (14A) in contact with the main surface (12A) of the semiconductor substrate (12) and a second surface (14B) opposite to the first surface (14A), and including a gate trench (42) recessed in the second surface (14B);

a split gate structure (SG) provided in the gate trench (42);

an insulating layer (16, 48) filling the gate trench (42) and covering the second surface (14B) of the semiconductor layer (14); and

a trap level region (TL; TL1; TL2; TL3; TL4) formed in any one the semiconductor layer (14) and the semiconductor substrate (12) to trap carriers moving from the semiconductor layer (14).

### (Supplementary Note A2)

The semiconductor device (10) of Supplementary Note A1, wherein the trap level region (TL; TL1; TL2) is formed in the semiconductor layer (14) at a position between a bottom surface of the gate trench (42) and the first surface (14A) of the semiconductor layer (14).

### (Supplementary Note A3)

The semiconductor device (10) of Supplementary Note A2, wherein the trap level region (TL; TL1) is formed at a position between a center position between the bottom surface of the gate trench (42) and the first surface (14A) of the semiconductor layer (14) and the first surface (14A) of the semiconductor layer (14).

### (Supplementary Note A4)

The semiconductor device (10) of Supplementary Note A2, wherein the trap level region (TL2) is formed at a position between a center position between the bottom surface of the gate trench (42) and the first surface (14A) of the semiconductor layer (14) and the bottom surface of the gate trench (42).

### (Supplementary Note A5)

The semiconductor device (10) of Supplementary Note A4, wherein the trap level region (TL; TL1; TL2) is formed at a depth position within 10 μm from the bottom surface of the gate trench (42), in a depth direction of the gate trench (42) from the second surface (14B) of the semiconductor layer (14) toward the first surface (14A) of the semiconductor layer (14).

### (Supplementary Note A6)

The semiconductor device (10) of Supplementary Note A1, wherein the semiconductor layer (14) includes:

a drift region (32) including the first surface (14A) of the semiconductor layer (14) and formed on the main surface (12A) of the semiconductor substrate (12);

a body region (34) formed on the drift region (32); and

a source region (36) including the second surface (14B) of the semiconductor layer (14) and formed on the body region (34),

wherein the trap level region (TL; TL1; TL2) is formed in the drift region (32).

### (Supplementary Note A7)

The semiconductor device (10) of any one of Supplementary Notes A1 to A6, wherein the trap level region (TL; TL1) is formed near an edge of a depletion layer when the depletion layer spreads a maximum in the semiconductor layer (14) during a reverse recovery operation.

### (Supplementary Note A8)

The semiconductor device (10) of Supplementary Note A1, wherein the trap level region (TL3; TL4) is formed at a depth position within 15 μm from the main surface (12A) of the semiconductor substrate (12), in a direction from the main surface (12A) of the semiconductor substrate (12) to the back surface (12B) of the semiconductor substrate (12).

### (Supplementary Note A9)

The semiconductor device (10) of any one of Supplementary Notes A1 to A8, wherein the trap level region (TL; TL1; TL2; TL3; TL4) is formed in a predetermined spread range in a thickness direction from a region center of the trap level region (TL; TL1; TL2; TL3; TL4), in the semiconductor layer (14) or the semiconductor substrate (12).

### (Supplementary Note A10)

The semiconductor device (10) of any one of Supplementary Notes A1 to A9, wherein the trap level region (TL; TL1; TL2; TL3; TL4) is formed by irradiation with any one of first heavy particles, second heavy particles having a larger particle mass than the first heavy particles, and electron beams.

### (Supplementary Note A11)

The semiconductor device (10) of Supplementary Note A10, wherein the first heavy particles include protons.

### (Supplementary Note A12)

The semiconductor device (10) of Supplementary Note A10, wherein the second heavy particles include ³He⁺⁺ or ⁴He⁺⁺.

The above description is merely an example. Those skilled in the art will appreciate that more possible combinations and substitutions are possible beyond the components and methods (manufacturing processes) listed for the purposes of illustrating the techniques of the present disclosure. The present disclosure is intended to cover all alternatives, modifications, and changes that fall within the scope of the present disclosure, including the claims.

According to the present disclosure in some embodiments, it is possible to provide a split gate structure MISFET capable of shortening a reverse recovery time.

While certain embodiments have been described, these embodiments have been presented by way of example only, and are not intended to limit the scope of the disclosures. Indeed, the embodiments described herein may be embodied in a variety of other forms. Furthermore, various omissions, substitutions and changes in the form of the embodiments described herein may be made without departing from the spirit of the disclosures. The accompanying claims and their equivalents are intended to cover such forms or modifications as would fall within the scope and spirit of the disclosures.

What is claimed is:

1. A semiconductor device comprising:
a semiconductor substrate including a main surface and a back surface opposite to the main surface;
a semiconductor layer including a first surface in contact with the main surface of the semiconductor substrate and a second surface opposite to the first surface, and including a gate trench recessed in the second surface;
a split gate structure provided in the gate trench;
an insulating layer filling the gate trench and covering the second surface of the semiconductor layer; and
a trap level region formed in any one of the semiconductor layer and the semiconductor substrate to trap carriers moving from the semiconductor layer.

2. The semiconductor device of claim 1, wherein the trap level region is formed in the semiconductor layer at a position between a bottom surface of the gate trench and the first surface of the semiconductor layer.

3. The semiconductor device of claim 2, wherein the trap level region is formed at a position between a center position between the bottom surface of the gate trench and the first surface of the semiconductor layer and the first surface of the semiconductor layer.

4. The semiconductor device of claim 2, wherein the trap level region is formed at a position between a center position between the bottom surface of the gate trench and the first surface of the semiconductor layer and the bottom surface of the gate trench.

5. The semiconductor device of claim 4, wherein the trap level region is formed at a depth position within 10 μm from the bottom surface of the gate trench, in a depth direction of the gate trench from the second surface of the semiconductor layer toward the first surface of the semiconductor layer.

6. The semiconductor device of claim 1, wherein the semiconductor layer includes:
a drift region including the first surface of the semiconductor layer and formed on the main surface of the semiconductor substrate;
a body region formed on the drift region; and
a source region including the second surface of the semiconductor layer and formed on the body region,
wherein the trap level region is formed in the drift region.

7. The semiconductor device of claim 1, wherein the trap level region is formed at a depth position within 15 μm from the main surface of the semiconductor substrate, in a direction from the main surface of the semiconductor substrate to the back surface of the semiconductor substrate.

8. The semiconductor device of claim 1, wherein the trap level region is formed by irradiation with any one of first heavy particles, second heavy particles having a larger particle mass than the first heavy particles, and electron beams.

9. The semiconductor device of claim 8, wherein the first heavy particles include protons.

10. The semiconductor device of claim 8, wherein the second heavy particles include ³He⁺⁺ or ⁴He^{++.}
